(19) United States
(12) Patent Application Publication
(10) Pub. No.: US 2005/0007198 A1
(43) Pub. Date: Jan. 13, 2005

(54) Power amplifier module

(76) Inventor: Marius Gerardus Jacobus Versteegen, Nijmegen (NL)

Correspondence Address: Philips Electronics North America Corporation;Intellectual Property & Standards, 1109 Mckay Drive M/ S41-SJ, San Jose, CA, 95131, US

(21) Appl. No.: 10/493,621

(22) PCT Filed: Oct. 18, 2002
(86) PCT No.: PCT/IB02/04338

(30) Foreign Application Priority Data
Oct. 23, 2001 (EP) 01204021.8

(51) Int. Cl. H03F 3/18

(52) U.S. Cl. 330/264

(57) ABSTRACT

The invention relates to a power amplifier module comprising single-ended amplifiers (101 and 102) which are arranged in a BTL configuration. The single-ended amplifiers (101 and 102) have low-impedance inverting inputs coupled by a resistor R1 for improved stability and quiescent current control.

### FIELD OF THE INVENTION

The invention relates to a power amplifier module and in particular to an audio power amplifier.

### BACKGROUND AND PRIOR ART

The prior art shows a variety of power amplifiers which can be used for audio applications. In particular, U.S. Pat. No. 5,216,381 shows a unitary-gain final stage particularly for monolithically integratable power amplifiers which use class AB-driven N-channel MOS transistors as power devices. This power amplifier comprises a high-gain feedback differential amplifier who's inverting input terminal is connected to the input of the power amplifier. This prior art amplifier has some major drawbacks: The quiescent current control is inaccurate and the stability is insufficient.

FIG. 1 shows a corresponding unitary-gain final stage comprising a pair of final N-channel MOS power transistors 1 and 2. The first transistor 1 has its drain terminal connected to a supply voltage 3 and its source terminal connected to the drain terminal of the second transistor 2. The source terminal of the second transistor 2 is connected to the ground. The output terminal 4 of the power amplifier is connected between the source terminal of the first transistor 1 and the drain terminal of the second transistor 2. A high-gain feedback differential amplifier 5 has an inverting input terminal which is connected to the input of the power amplifier. The non-inverting input terminal of the differential amplifier 5 is connected to the output terminal 4 of the amplifier, and the output terminal of said differential amplifier 5 is connected to the gate terminal of the second transistor 2. A leveling circuit 6 is furthermore connected to the gate terminal of the second transistor 2. A third MOS transistor 7 is provided and has its source terminal connected to the input of the power amplifier; the gate terminal and the drain terminal of the third MOS transistor 7 are connected to the gate terminal of the first transistor 1 and to a first current source 8.

U.S. Pat. No. 5,361,041 shows a similar circuit arrangement comprising a push-pull amplifier having a driver circuit for driving a source follower output transistor. The driver circuit includes a replicating transistor having electrical characteristics substantially similar to those of the source follower transistor, a buffer amplifier, and a circuit, coupled to the replicating transistor and the buffer amplifier, for summing the voltage across the replicating transistor and the buffer output signal to provide a gate signal to the source follower output transistor. A cross current feedback circuit regulates the quiescent current flow through the output transistors by adjusting the gate signal provided to the upper, source follower output transistor in response to a sensed current flow through the lower output transistor.

U.S. Pat. No. 5,973,564 shows a typical alternative for controlling quiescent currents through power transistors. That is, the currents that flow through each of the power transistors of a final stage are fed into minimum selector. The minimum current thus measured is compared with a reference by a comparator. The comparator output then normally increases or decreases the quiescent current level as needed. For large exitations however, this quiescent current control loop is no longer orthogonal to the signal loop. As a result, overall stability is compromised. That can be counteracted by making the gain of the quiescent current control loop low, but that would result in an inaccurate quiescent current control.

U.S. Pat. No. 4,539,529 shows a semiconductor amplifier circuit including first and second operational amplifiers, and first and second voltage dividers connected between the outputs of the first and second operational amplifiers, respectively, and a reference potential source. First and second resistors are connected between the divider point of the first and second voltage dividers, respectively, and the inverting input of the first and second operational amplifiers, respectively, forming real negative feedbacks.

A first signal input terminal of the amplifier circuit is connected to the non-inverting input of the first and second operational amplifiers, respectively. A third common voltage divider is connected between the reference potential source and a supply potential source. A common intermediate resistor is connected to the divider point of the common voltage divider, and first and second supply resistors are connected in series with the intermediate resistor. The first and second supply resistors are connected between the intermediate resistor and the non-inverting input of the first and second operational amplifiers, respectively. The first resistor has a resistance substantially equal to the sum of the resistance of the first supply resistor and twice the resistance of the intermediate resistor. The second resistor has a resistance substantially equal to the sum of the resistance of the second supply resistor and twice the resistance of the intermediate resistor. One of the deficiencies of this amplifier circuit is that this configuration can not be used for asymmetrical inputs.

For audio power amplifiers two serially cascaded inverting amplifiers are often used in a BTL configuration to drive a load, e.g. a speaker, with a differential output signal. Such audio power amplifiers are commercially available from Philips Electronics N.V., for example the TDA 8941P audio amplifier.

It is an object of the present invention to provide an improved power amplifier module which overcomes the disadvantages featured by the prior art.

The solution of the underlying problem of the invention is provided by applying the features laid down in the independent claims. Preferred embodiments of the invention are given in the dependent claims.

The present invention is advantageous in that it provides a power amplifier module featuring precise quiescent current control and enhanced stability.

A further advantage of the present invention is that the quiescent current control can be made very accurate without compromising stability. Another advantage is that the invention enables a circuit configuration which can be used for asymmetrical inputs.

Further the invention is especially applicable in BiMos processes, like Philips semiconductors ABCD process. In such processes, the thermo-dynamical robustness of low RdsOn of MOST power transistors can be exploited along with the high transeonductance and low noise of small bipolar transistors.

According to a preferred embodiment of the invention the inverting inputs of the single-ended amplifiers are low-impedance current inputs compared to the resistor coupling the inverting inputs up to high frequencies. This way feedback transadmittances of both amplifiers remain constant. This way the amplifiers barely “see” each other and good stability is retained.

In accordance with a further preferred embodiment of the invention each single-ended amplifier has an npn-transistor as an input stage. This way a common compensation can be reached as a result of using a single input transistor for each single-ended amplifier. Compensation currents to the inverting inputs of both single-ended amplifiers need to be applied.

Applications for a power amplifier module in accordance with the invention include mains fed applications, e.g. TV sound, PC audio, portable audio, car audio systems and all other kinds of audio and sound systems. However the present invention is not limited to the field of amplification of audio signals but can be employed for other kinds of signals as well. For example the present invention can be employed for other applications requiring high stability at inductive loads and low prices due to mass-market requirements, such as motordrivers.

### BRIEF DESCRIPTION OF THE DRAWING

In the following a preferred embodiment of the invention is described in greater detail by making reference to the drawings in which:

FIG. 1 a circuit diagram of a prior art unitary-gain final stage,

FIG. 2 is a circuit diagram of a preferred embodiment of a power amplifier module in accordance with the invention,

FIG. 3 is a circuit diagram of an input configuration for the power amplifier module of FIG. 1,

FIG. 4 is a circuit diagram of a first embodiment of a backend module of the power amplifier module of FIG. 1,

FIG. 5 is a second preferred embodiment of a backend module of the power amplifier module of FIG. 1.

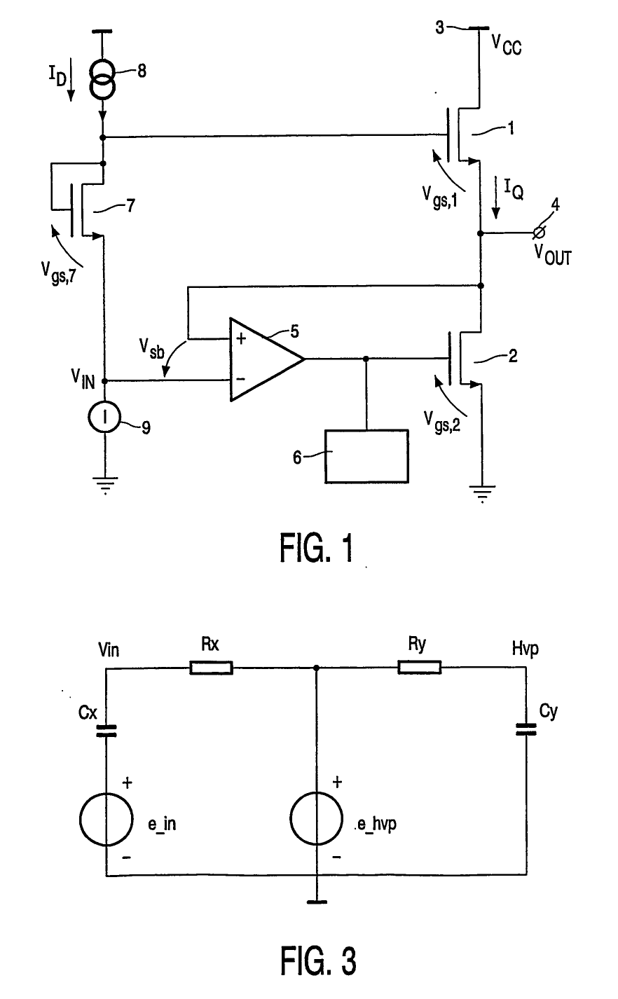

### DETAILED DESCRIPTION

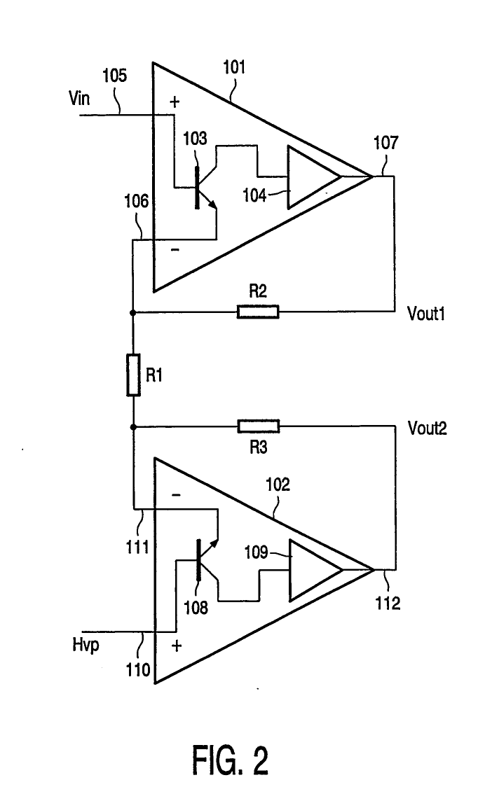

FIG. 2. shows a circuit diagram of a power amplifier module in accordance with the invention. The power amplifier module comprises a single-ended amplifier 101 and a single-ended amplifier 102. In general terms a single-ended amplifier is an amplifier which has a single output terminal that operates with respect to ground. The voltage difference between the input terminal and the ground is amplified.

The single-ended amplifier 101 comprises an npn-transistor 103 and a backend module 104. The bias terminal of the transistor 1033 is connected to the non-inverting terminal 105 of the single-ended amplifier 101 and the emitter of the transistor 103 is connected to the inverting terminal 106 of the single-ended amplifier 101. The collector of the transistor 103 is connected to the input of the backend module 104. The output of the backend module 104 is connected to the output terminal 107 of the single-ended amplifier 101.

The single-ended amplifier 102 has a corresponding npn-transistor 108 and a backend module 109. The base of the transistor 108 is connected to the non-inverting terminal 110 of the single-ended amplifier 102 and the source of the transistor 108 is connected to the inverting terminal 111 of the single-ended amplifier 102. The drain of the transistor 108 is connected to the input of the backend module 109. The output of the backend module 109 is connected to the output terminal 112 of the single-ended amplifier 102.

Essentially, the backend modules 104 and 109 each implement an integrating IV converter.

A resistor R1 is coupled between the terminal 106 of the single-ended amplifier 101 and the terminal 111 of the single-ended amplifier 102. Further a resistor R2 is connected between the terminals 106 and 107 and a resistor R3 connects the terminals 111 and 112. By means of the resistors R2 and R3 a feedback component from the respective output terminals 107 and 112 is provided.

In operation an input voltage Vin is applied to the terminal 105 and a power supply reference voltage Hvp is applied to the terminal 110. In order to obtain maximum output swing without clipping, it's value is normally chosen to be half of the power supply voltage (Vp). This produces the voltages Vout1 and Vout2 at the terminals 107 and 112, respectively. The voltages Vout1 and Vout2 are used to drive the load in a BTL configuration.

The inverting input terminals 106 and 111 of the single ended amplifiers 101 and 102, respectively are low-impedance current-inputs compared to R1 up to high frequencies. The transfer function of the feedback loop thus retains a transadmittance factor of (1/R2) and (1/R3) for amplifier 101 and 102, respectively. As a consequence, both single-ended amplifiers 101 and 102 barely “see” each other. Thus, even at high frequencies, the loopgain of amplifier 101 is not deteriorated by the loopgain of amplifier 102 and vice versa. That way, stability is kept optimal.

As a result of using a single input transistor—transistor 103 and transistor 108, respectively—for each single-ended amplifier 101 and 102, the output voltage is lower than Hvp. This can be compensated by applying compensation currents to the inverting input terminals 106 and 111 with values of Vd/R2 and Vd/R3, respectively, where Vd is the voltage of a forward biased diode, or alternatively by increasing Hvp by Vd.

With an asymmetrical input signed as considered here the resistors R2 and R3 should be chosen to have a different value, such that the common mode output voltage remains fixed, preferably in order to keep 0.5% clipping-distortion-output power at maximum in order to maximize the unclipped differential output voltage swing. A good choice is R3=R1+R2. In this case the gain becomes 2×R3/R1.

It is to be noted that the input signal is asymmetrical. If desired a symmetrical input signal can be used as well where the terminal 106 has a voltage of Hvp+Vin and the terminal 110 has a voltage of Hvp−Vin. For economical reasons in car radios mostly asymmetric input signals are used due to the cost-saving effect of sharing ground lines and a number of capacitors when combining channels. In order to maximize output power symmetric (differential) output signals are applied to the load.

FIG. 3 shows a circuit diagram depicting an input configuration for the power amplifier module of FIG. 2. The voltage e_in is an audio signal which needs to be amplified, e.g. an output signal of a CD-player. This signal is filtered by means of a capacitor Cₓ to provide the voltage applied at the terminal 105 (cf. FIG. 2) which is Vin.

Further a reference voltage e_hvp is provided. This voltage is applied between ground and the connection of two resistors Rₓ and R_{y}. The other terminal of the resistor Rₓ is connected to Vin and the other terminal of the resistor R_{y} is providing the voltage Hvp which is applied to the terminal 110 (cf. FIG. 2). Further there is a filtering capacitor C_{y} connected between the resistor R_{y} and ground. Hvp is a fixed voltage. Vin is a signal that swings around Hvp.

That is, unlike symmetrical inputs, where one input rises as the other input lowers, here, we have an asymmetric input: one half is fixed, the other moves. As a result, the common mode output voltage (Vout1+Vout2)/2 would not be fixed at Hvp if (R3=R2) is chosen. As a result, the output signal would clip to the supplies earlier, resulting in a (differential-) clipping distortion. For that reason, R3=R1+R2 is being chosen. That way, the common mode output voltage will remain exactly equal to Hvp for each value of Vin. Thus, the differential output signal that can be generated without clipping, can be maximized. As the distortion of integrated audio amplifiers is typically below 0.05%, clipping detection circuitry normally “fires” at measured distortions of about 0.5%.

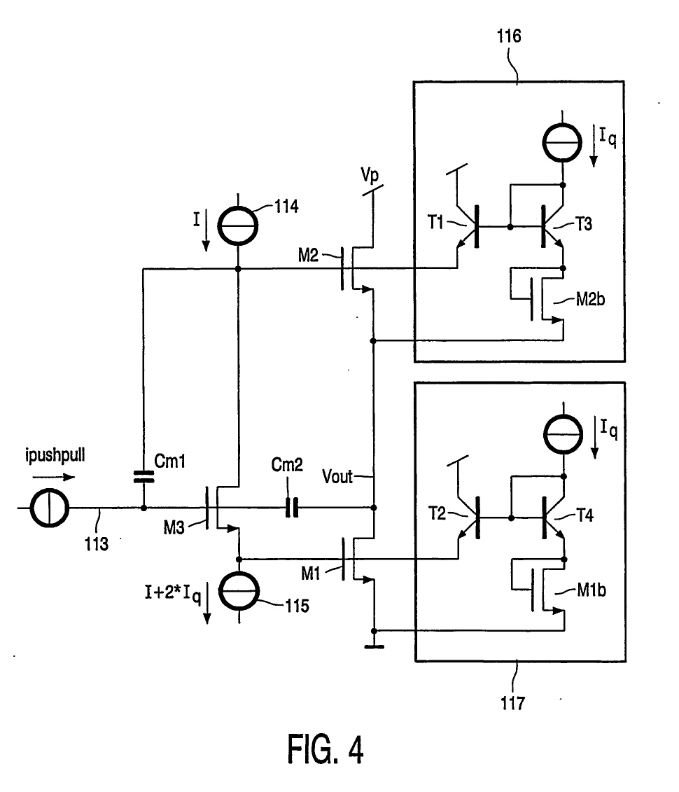

FIG. 4 shows a circuit diagram of a preferred embodiment of the backend modules 104 and 109, respectively. A capacitor Cm1 is connected to the input terminal of the backend module. The other terminal of the capacitor Cm1 is connected to the gate of a power transistor M2. Further the gate of the transistor M3 is connected to the input terminal 113 of the backend module. A current source 114 is coupled to the gate of the transistor M2 and to the drain of the transistor M3. The source of the transistor M3 is coupled to a current sink 115. The current source 114 provides the current I and the current sink 115 sinks the current I+2×Iq.

Further the source of the transistor M3 is connected to the base of the power transistor M1. A capacitor Cm2 is connected to the base of the transistor M3 and to the source of the power transistor M2 and to the drain of the power transistor M1. At this point the output voltage Vout is provided.

Further the backend module has clamps 116 and 117. The quiescent current control is implemented by using the clamps 116 and 117. The current Iq is fed into mirror-most M2b. The clamp voltage which is obtained this way, is applied to the gate of M2 via clamp transistors T1 and T3. Using npn's for these transistors keeps the error of the clamping voltage low, which is important, as in quiescent conditions, M2 and M1 tend to operate in weak inversion.

During quiescent conditions, there's no voltage drop across the load. Therefore, no current leaves the amplifier. Consequentially, the currents in M1 and M2 must be equal, and so do their Vgs voltages. That in turn results in equal clamp currents through T1 and T2. According to Kirchoff's current law, T1, T2, T3, T4, M1b and M2b should all conduct a current equal to Iq. The quiescent current through M1 and M2 thus becomes: Iq times the ratio of the areas between M1b and M1, and between M2b and M2 respectively.

There is an additional advantage of this quiescent current control. The emitters of the clamps help to lower the impedance's at the gates of the powers. That way, the corresponding (sub-dominant-) poles are moved to a higher frequency, improving stability of the amplifier.

In accordance with a preferred embodiment the drain of M3 is not connected directly to the gate of M2, but via a folded cascode. This cascode also cascodes current source 114 to ensure that the output voltage is rail to rail without choking M3.

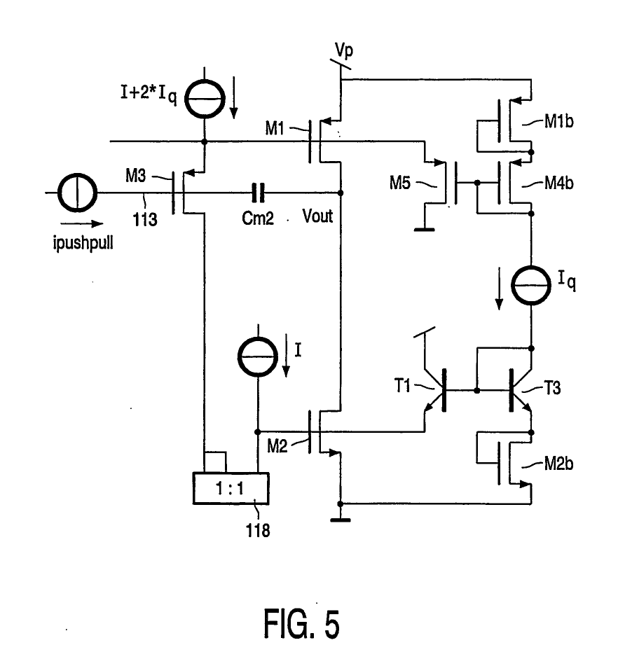

FIG. 5 shows a further preferred embodiment for the backend module. In comparison to the implementation of FIG. 4 the power transistors M1 and M2 are complementary for improved audio quality. In this embodiment the drain of the miller transistor M3 is connected to the current mirror 118.

List of reference numerals

transistor 1
transistor 2
supply voltage 3
output terminal 4
amplifier 5
leveling circuit 6
transistor 7
current source 8
single-ended amplifier 101
single-ended amplifier 102
transistor 103
backend module 104
terminal 105
terminal 106
terminal 107
transistor 108
backend module 109
terminal 110
terminal 111
terminal 112
input terminal 113
current source 114
current sink 115
clamp 116
clamp 117
current mirror 118

1. A power amplifier module comprising a first single-ended amplifier and a second single-ended amplifier arranged in a Bridge Tied Load configuration, the first and the second single-ended amplifiers having first and second low-impedance inverting inputs, respectively, coupled by a first resistive element.

2. The power amplifier module of claim 1 the first single-ended amplifier having a first non-inverting input terminal for receiving an input voltage and the second single-ended amplifier having a second non-inverting input terminal for receiving a power supply voltage or the inverted input voltage in case of a fully differential input signal.

3. The power amplifier module of claim 1 the first and the second single-ended amplifiers each having an NPN-transistor as an input stage, the emitters of the NPN-transistors being coupled to the first and the second low-impedance inverting inputs, respectively.

4. The power amplifier module of claim 1, the first single-ended amplifier having a second resistive element to provide a first feedback component and the second single-ended amplifier having a third resistive element to provide a second feedback component, the total resistance of the first and second resistive elements being equal to the resistance of the third resistive element.

5. The power amplifier module of claim 1 4, each of the first and the second single-ended amplifiers comprising a backend module with quiescent current control.

6. The power amplifier module of claim 5, each of the backend modules comprising first and second clamps.

7. The power amplifier module of claim each of the backend modules comprising a complementary pair of power transistors.

8. The power amplifier module of claim 5, each of the backend modules comprising a current mirror.
